(19) United States
(12) Patent Application Publication
(10) Pub. No.: US 2009/0277393 A1
(43) Pub. Date: Nov. 12, 2009

(54) SOLAR BIRD HOUSE

(76) Inventors: Gregory G. Kuelbs, Westlake, TX (US); Gustav P. Kuelbs, Grapevine, TX (US)

Correspondence Address: LAW OFFICES OF JAMES E. WALTON, PLLC, 1169 N. BURLESON BLVD., SUITE 107-328, BURLESON, TX, 76028, US

(21) Appl. No.: 12/467,946

(22) Filed: May 18, 2009

Related U.S. Application Data
(63) Continuation-in-part of application No. 11/284,244, filed on Nov. 21, 2005, now abandoned.
Application No. 11/284,244 is a continuation-in-part of application No. 11/257,728, filed on Oct. 25, 2005, now Pat. No. 7,540,262.
Application No. 11/257,728 is a continuation-in-part of application No. 11/063,059, filed on Feb. 22, 2005, now Pat. No. 7,017,521.
Application No. 11/063,059 is a continuation of application No. 10/847,973, filed on May 18, 2004, now Pat. No. 6,901,882.
Application No. 10/847,973 is a continuation of application No. 10/411,565, filed on Apr. 10, 2003, now Pat. No. 6,830,009.
(60) Provisional application No. 60/630,327, filed on Nov. 23, 2004.
(60) Provisional application No. 60/372,267, filed on Apr. 11, 2002.

(51) Int. Cl. A01K 31/00; H01L 31/00

(52) U.S. Cl. 119/428; 136/251

(57) ABSTRACT

A solar powered bird house having solar energy system for powering an electrical subsystem is disclosed. The electrical subsystem may include lighting elements for illuminating the bird house and the area around the bird house in a decorative and functional manner.

This application is a continuation-in-part of U.S. application Ser. No. 11/284,244, filed 21 Nov. 2005, titled “Solar Bird House,” which is hereby incorporated by reference, and which claims the benefit of U.S. Provisional Application No. 60/630,327, filed 23 Nov. 2004, titled “Solar Bird House,” which is hereby incorporated by reference. This application is also a continuation-in-part of U.S. application Ser. No. 11/257,728, filed 25 Oct. 2005, titled “Solar Powered Bird Feeder,” which is hereby incorporated by reference, and which is a continuation-in-part of U.S. application Ser. No. 11/063,059, filed 22 Feb. 2005, titled “Solar Powered Bird Feeder,” which issued on 28 Mar. 2006 under U.S. Pat. No. 7,017,521, which is hereby incorporated by reference, and which is a continuation of U.S. application Ser. No. 10/847,973, filed 18 May 2004, titled “Solar Powered Bird Feeder,” which issued on 7 Jun. 2005 under U.S. Pat. No. 6,901,882, which is hereby incorporated by reference, and which is a continuation of U.S. application Ser. No. 10/411,565, filed 10 Apr. 2003, titled “Solar Powered Bird Feeder,” which issued on 14 Dec. 2004 under U.S. Pat. No. 6,830,009, which is hereby incorporated by reference, and which claims the benefit of U.S. Provisional Application No. 60/372,267, filed 11 Apr. 2002, titled “Solar Powered Bird Feeder,” which is hereby incorporated by reference.

### BACKGROUND OF THE INVENTION

1. Field of the Invention

The present invention relates in general to the field of bird houses.

2. Description of Related Art

There are many designs of bird houses well known in the art. Bird houses are typically used outdoors; however, some bird houses are primarily decorative and are used indoors or outdoors in an area that is protected from the environment. At night, or in otherwise poorly illuminated locations, it is difficult to visually inspect the bird house, the contents of the bird houses, or fully appreciate the decorative nature of the bird house. While there are many bird houses well known in the art, considerable room for improvement remains.

### SUMMARY OF THE INVENTION

There is a need for a solar powered bird house.

Therefore, it is an object of the present invention to provide a solar powered bird house.

This object is achieved by providing a solar powered birdhouse having solar energy system and a rechargeable electrical power source that is recharged, at least partially, by the solar energy system. The electrical power is used to power lighting elements or other electrical subsystems operably associated with the bird house.

The present invention provides significant advantages, including: (1) the bird house and/or the contents of the bird house can be selectively illuminated for visual inspection at night or when the bird house is located in a poorly illuminated space while minimizing any light pollution to the interior of the bird house; (2) decorative elements of the bird house can be illuminated; (3) other electrical subsystems, such as sound systems, microphone systems, electrical receivers and transmitters, and various electromechanical systems can be operably associated with the birdhouse; and (4) existing bird houses with no electrical subsystems can be quickly and easily retrofitted with a solar powered electrical subsystem.

Further objects and advantages of this invention will become apparent from a consideration of the drawings and ensuing description.

### BRIEF DESCRIPTION OF THE DRAWINGS

For a more complete understanding of the present invention, including its features and advantages, reference is now made to the detailed description of the invention taken in conjunction with the accompanying drawings in which like numerals identify like parts, and in which:

FIG. 1 is a perspective view of a solar powered bird house system according to the present invention;

FIG. 2 is a front view of an alternate embodiment of a bird house system according to the present invention;

FIG. 3 is a perspective view of another alternate embodiment of a bird house system according to the present invention;

FIG. 4 is a perspective view of another alternate embodiment of a bird house system according to the present invention; and

FIG. 5 is a perspective view of another alternate embodiment of a bird house system according to the present invention.

### DETAILED DESCRIPTION OF THE PREFERRED EMBODIMENT

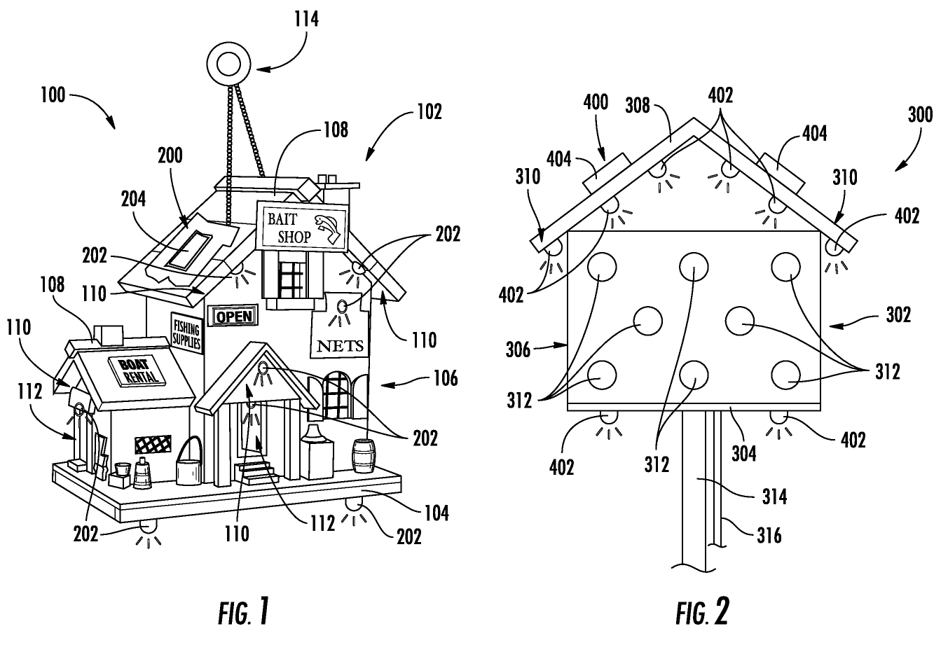

Referring to FIG. 1 in the drawings, the preferred embodiment of a bird house system 100 according to the present invention is illustrated. Bird house system 100 preferably comprises a bird house 102 and a solar energy system 200 for supplying electrical energy to at least one electrical subsystem. Bird house 102 preferably comprises a base 104, at least one enclosure 106, at least one top 108, at least one optional overhang 110, at least one access hole 112, and a hanging accessory 114.

Bird house 102 is preferably generally shaped and sized as a scale model architectural structure. Base 104 is preferably a flat member representative of the ground and upon which enclosure 106 is affixed. Enclosure 106 is preferably shaped as a decorative scale model home or storefront building having multiple architectural elements. For example, enclosure 106 is illustrated as having exterior walls, doors, windows, chimneys, and porches. Tops 108 are preferably roof-like members attached to enclosure 106 and decoratively represent complementary roofs to enclosure 106. Top 108 preferably aids in preventing water, dirt, and other outdoor particulate matter from entering enclosure 106. Overhangs 110 are optional portions of tops 108 that extend beyond the extents of the decorative exterior walls of enclosure 106. Access holes 112 are preferably holes in the exterior walls of enclosure 106 which provide birds ingress and egress to the interior space of enclosure 106. Hanging accessory 114 is preferably a chain and loop feature attached to top 108, and is preferably used to suspend bird house system 100 from a support structure (not shown). Hanging accessory 114 has been shown as a hook, but may alternatively be a clasp, ring, clip, or other device suitable for suspending bird house system 100.

Solar energy system 200 provides electrical energy to one or more electrical subsystems. Solar energy system 200 is preferably substantially housed within enclosure 106; however, it will be appreciated that in some embodiments of the present invention, one or more components of solar energy system 200 may be located remote from enclosure 106. The components of solar energy system 200 are preferably substantially protected such that water, dirt, and other outdoor particulate matter is prevented from interfering with the operation of solar energy system 200.

Solar energy system 200 preferably comprises a rechargeable electrical power source and a solar energy recharging system for converting solar energy into electrical energy. Solar energy system 200 is conductively coupled to one or more electrical subsystems, such as lighting systems, sound systems, video systems, microphone systems, receiving and transmitting systems, motion actuating systems, cooling systems, heating systems, raising and lowering systems, and other electrically powered subsystems. The solar energy recharging system includes at least one solar collector 204 for receiving and collecting solar energy. Solar collector 204 may be located at any suitable location on or about bird house system 100; however, it is preferred that solar collector 204 be optimally exposed to solar light. Solar collector 204 is preferably attached to top 108, but may alternately be located remote from 108. For those applications in which bird house is primarily a decorative piece displayed indoors, it may be desirable to locate solar collector 204 at a location on bird house 102 that is near or faces a window, or on a remote solar energy collecting device.

In the preferred embodiment, bird house 102 is configured with at least one lighting subsystem comprising at least one lighting element 202, conductive elements, and circuitry for operating and controlling lighting elements 202. Lighting elements 202 may be operably associated with the bottom of base 104, the exterior walls of enclosure 106, the interior of enclosure 106, and overhangs 110. Lighting elements 202 illuminate bird house system 100 and/or the space in and around bird house system 100. Specifically, lighting elements 202 are arranged to illuminate bird house system 100 in a manner decoratively representative of how a full-sized storefront building having multiple architectural elements might be illuminated. For example, lighting elements 202 may be configured as porch lights and disposed on the exterior of birdhouse 102, so as to illuminate signs or other features on the exterior of bird house 102.

In order to protect the health and/or natural behavior of the birds which inhabit or otherwise use the interior of enclosure 106, it is important that if necessary, the circuitry for operating and controlling lighting elements 202 include sensors, switches, and/or remote control devices for minimizing illumination of the interior of enclosure 106. More specifically, lighting elements 202 not located in the interior of enclosure 106 are preferably arranged not illuminate the interior of enclosure 106. Further, any lighting elements 202 arranged and/or located to illuminate the interior of enclosure 106 are preferably controlled automatically and/or manually to illuminate the interior of enclosure 106 only when illuminating the interior of enclosure 106 is not significantly harmful to the health and/or natural behavior of the birds which inhabit or otherwise use the interior of enclosure 106. Of course, any automatic means for limiting illumination of the interior of enclosure 106 is preferably optionally manually bypassed by the user to provide the user with the ability to visually inspect the interior of enclosure 106 at any time so desired.

The rechargeable electrical power source is preferably a rechargeable battery; however, the rechargeable electrical power source may be any renewable power source, such as capacitors, fuel cells, battery packs, or any other suitable device for storing electrical power. The rechargeable electrical power source is connected to each electrical subsystem by conventional electrical connectors, such as wires or circuit boards.

In operation, solar energy system 200 receives and collects solar energy, and then converts the solar energy into electrical energy. The electrical energy is then used to provide a trickle charge to the rechargeable electrical power source. The rechargeable electrical power source is conductively coupled to lighting elements 202, where the electrical energy is converted into light energy. Of course, the rechargeable electrical power source may be connected to other electrical subsystems, as well, such as sound systems, microphone systems, electrical receivers and transmitters, and various electromechanical systems, including electrical motors for actuating various components and features of bird house 102. Lighting elements 202 are preferably light emitting diodes, but may be organic light emitting diodes, incandescent bulbs, cold cathode ray tubes, fluorescent lights, or any other suitable electrical lighting apparatus, or combination thereof.

The rechargeable electrical power source may be recharged by means other than solar energy system 200. For example, the rechargeable power system may alternately comprise a rechargeable battery pack, in which the battery pack is removed from solar energy system 200, recharged remotely from solar energy system 200, and thereafter replaced back into solar energy system 200 to again supply electrical energy to lighting elements 202. Of course, the foregoing configuration allows for the interchanging, or swapping, of battery packs. Also, the rechargeable electrical power source may include an AC-to-DC converter, such that the rechargeable battery may be recharged by externally supplied alternating current from a conventional AC outlet.

Alternate embodiments of solar energy system 200 may not include the rechargeable power system. Instead, solar energy system 200 may include a circuit for powering lighting element 202 that can only operate with externally supplied electrical energy, either AC or disposable batteries.

In an alternate embodiment, a photo resistor, or photo cell 301, may be incorporated into solar light system 200. Photo cell 301 is preferably mounted on top 108. Photo cell 301 detects the presence of light and controls whether lighting elements 202 provide illumination, by switching lighting elements 202 on or off, or by regulating the intensity of light provided by lighting elements 202. For example, when photo cell 301 detects a substantial amount of light, lighting elements 202 are switched off and provide no illumination. However, when photo cell 301 detects a low level of light, lighting elements 202 are switched on and provide illumination. Alternately, photo cell 301 may be used to dim or brighten the output of lighting elements 202. In addition, one or more on-off switches or buttons may be incorporated to facilitate the operation of solar light system, or to vary the operation and control of the various components of bird house system 100. It will be appreciated that the operation of the various components of the bird house system of the present invention may be controlled remotely by infrared, radio, or other types of transmitters and receivers.

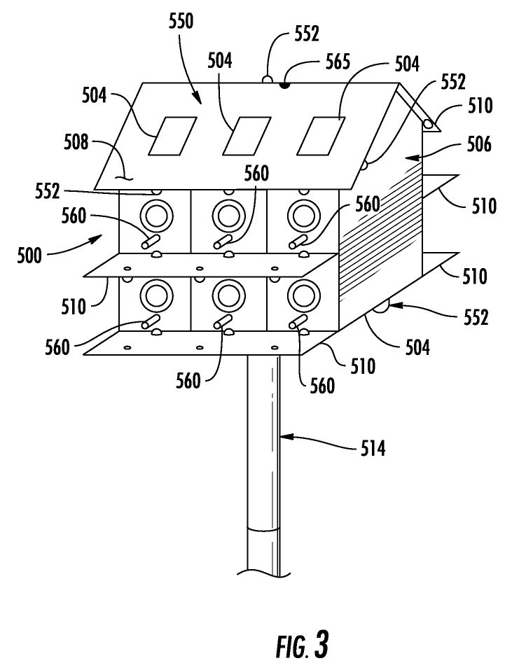

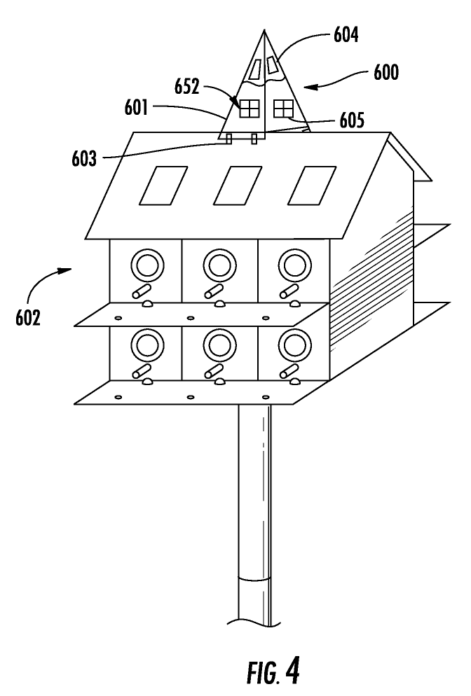

Referring now to FIG. 2 in the drawings, an alternate embodiment of a bird house system 300 according to the present invention is illustrated. Bird house system 300 preferably comprises a bird house 302 and a solar energy system 400. Bird house 302 preferably comprises a base 304, an enclosure 306, a top 308, at least one optional overhang 310, at least one access hole 312, and a support pole 314. Bird house 302 is preferably generally shaped and decoratively structured to accommodate colonizing birds, such as purple martins. Bird house 302 is preferably slidingly attached to support pole 314, such that bird house 302 may be raised and lowered by a conventional cable system 316. It will be appreciated the cable system 316 for raising and lowering bird house 302 may be one of the electrical subsystems powered by solar energy system 400. Enclosure 306 is preferably a four-walled structure rigidly attached to base 304 and having a plurality of nesting compartments, each with an access hole 312 to allow birds ingress and egress to the compartments within enclosure 306. Top 308 is preferably a sloped roof-like structure attached to the top of enclosure 306. Top 308 prevents water, dirt, and other outdoor particulate matter from entering enclosure 306 from above. Optional overhangs 310 are present where top 308 extends beyond the extents of enclosure 306. As shown in FIGS. 3-5, additional overhangs may be provided between each row of compartments. In addition, perches may be supplied beneath each opening. Of course, as with bird house system 100, lighting elements 202 and the various means for controlling lighting elements 202 are controlled in a manner consistent with preserving the health and/or natural behavior of the birds which inhabit or otherwise use the interior of enclosure 306.

Solar energy system 400 is substantially similar to solar energy system 200 and comprises a rechargeable electrical power source and at least one solar collector 404. Solar energy system 400 provides electrical power to the electrical subsystems operably associated with bird house system 300. One variance between solar energy system 400 and solar energy system 200 is the location of lighting elements 402. Because bird house 302 is configured to be raised up on pole 314, some lighting elements 402 have been located along the bottom of base 304.

Referring now to FIG. 3 in the drawings, another embodiment of a bird house system 500 according to the present invention is illustrated. Bird house system 500 includes a colony-type bird house 502, a support member 514, and a solar energy system 550 for providing electrical power to one or more electrical subsystems. Bird house 502 includes a base 504, a top 508, one or more optional overhangs 510, and a plurality of compartments located within an enclosure 506. A perch 560 may be associated with each compartment. At least one solar collector 504 is disposed on top 508. Bird house system 500 includes at least an electrical lighting subsystem having at least one lighting element 552. Lighting elements 552 may be located at various locations on bird house 502, such as on top of top 508, underneath overhangs 510, underneath base 504, on perches 560, and inside the compartments or other interior features of bird house 502. It will be appreciated that lighting elements 552 may be oriented to shine light either onto bird house 502 or away from bird house 502. Bird house system 500 may include a connection port 565 with which other electrical devices or power sources may be connected. Of course, as with bird house system 100, lighting elements 202 and the various means for controlling lighting elements 202 are controlled in a manner consistent with preserving the health and/or natural behavior of the birds which inhabit or otherwise use the interior of enclosure 506.

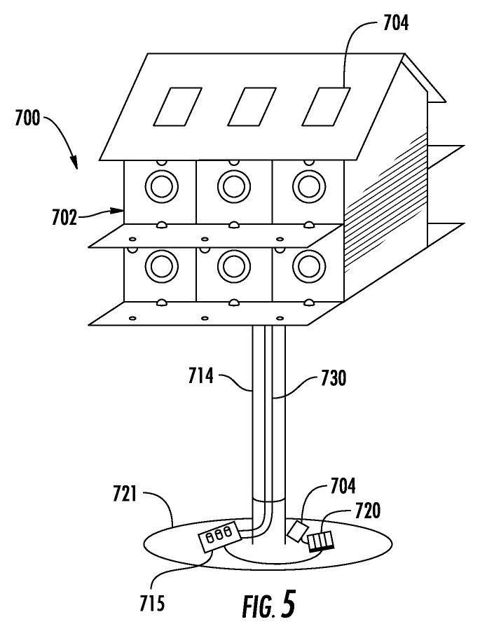

Referring now to FIG. 4 in the drawings, another embodiment of the present invention is illustrated. This embodiment is a retrofit embodiment in which a solar energy system 600 and at least one electrical subsystem, such as a lighting subsystem, has been retrofitted onto an existing bird house 602. In the example of FIG. 4, bird house 602 is a colony-type bird house; however, it should be understood that the retrofit embodiment of FIG. 4 may be used with any type of bird house, bird bath, bird feeder, or any other type of outdoor decorative accessory. Solar energy system 600 is carried within a housing 601 that is adapted to be quickly and easily attached to bird house 602 by conventional fastening means 603. The lighting subsystem includes at least one lighting element 652. Lighting element 652 may be located on the exterior or within the interior of bird house 602, or both. As is shown, housing 601 may be configured in the shape of a steeple or any other decorative structure of feature, and may include translucent windows or doors 605 through which light from interior lighting elements may shine. Of course, as with bird house system 100, lighting elements 202 and the various means for controlling lighting elements 202 are controlled in a manner consistent with preserving the health and/or natural behavior of the birds which inhabit or otherwise use the interior of bird house 602.

Solar energy system 600 includes a rechargeable electrical power source and at least one solar collector 604. Additional or larger solar collectors 604 may be disposed on bird house 602. Solar energy system 600 receives and collects solar energy, and then converts the solar energy into electrical energy that is used to provide a trickle charge to the rechargeable electrical power source for providing electrical energy to the electrical subsystems. Because all of the components of solar energy system 600 and other electrical subsystems may be completely contained within housing 601, solar energy system 600 is particularly well suited as a retrofit application for virtually any existing non-powered A-frame or flat-topped bird houses or bird feeders. This retrofit capability allows older, conventional bird houses and birds feeders to be converted into beautiful illuminated accessories that may be enjoyed at any hour of the day or night.

Referring now to FIG. 5 in the drawings, another embodiment a bird house system 700 according to the present invention is illustrated. Bird house system 700 comprises a bird house 702, a support member 714, a base 721, at least one electrical subsystem, and an optional solar energy system 720, similar to the solar energy systems described above. Of course, as with bird house system 100, lighting elements 202 and the various means for controlling lighting elements 202 are controlled in a manner consistent with preserving the health and/or natural behavior of the birds which inhabit or otherwise use the interior of bird house 702. Each electrical subsystem is powered by a rechargeable electrical power source 715. Rechargeable electrical power source 715 is preferably one or more rechargeable batteries; however, rechargeable electrical power source 715 may be any renewable power source, such as capacitors, fuel cells, battery packs, or any other suitable device for storing electrical power. In those embodiments of bird house system 700 in which rechargeable electrical power source is a rechargeable battery pack, the battery pack may be removed, recharged remotely, and thereafter replaced to again supply electrical energy to the electrical subsystems. Of course, the foregoing configuration allows for the interchanging, or swapping, of battery packs. Also, rechargeable electrical power source 715 may include an AC-to-DC converter, such that rechargeable electrical power source may be recharged by externally supplied alternating current from a conventional AC outlet. It will be appreciated that bird house system 700 may include one or more electrical ports that allow rechargeable electrical power source 715 to be by-passed, such that electrical power is supplied directly from a conventional AC outlet to an AC-to-DC converter.

Rechargeable electrical power source 715 is preferably housed in base 721, but may also be located in other locations, such as within support member 714, or within bird house 702. Rechargeable electrical power source 715 is connected to each electrical subsystem by conventional electrical connectors, such as wires 730 or circuit boards. Wires 730 may be passed through the interior of base 721 and support member 714. In the preferred embodiment, rechargeable electrical power source 715 is conductively coupled to and recharged by optional solar energy system 720. Solar energy system 720 includes at least one solar collector 704 for receiving and collecting solar energy. Solar collectors 704 may be located at various locations on bird house system 700, but are best located either on top of bird house 702 or on top of base 721.

Rechargeable electrical power source 715 is conductively coupled to and provides electrical power to the electrical subsystems, which may include lighting systems, sound systems, video systems, microphone systems, receiving and transmitting systems, motion actuating systems, cooling systems, heating systems, raising and lowering systems, and other electrically powered subsystems.

It will be appreciated that each embodiment of the present invention may be configured such that different power sources may be utilized, including rechargeable electrical power sources, trickle charges from solar energy systems, conventional AC outlets, and various combinations thereof. The various components of the various systems may be located in different locations of each bird house system, including in the bird houses, in the support members, and in the bases. In addition, it will be appreciated that each electrical subsystem may include selected components, circuitry, and microprocessor control chips to produce selected effects, such as blinking lights, fading lights, multi-color lighting, various audio effects, and a wide variety of motion effects.

While this invention has been described with reference to an illustrative embodiment, this description is not intended to be construed in a limiting sense. Various modifications and other embodiments of the invention will be apparent to persons skilled in the art upon reference to the description.

What is claimed is:

1. A solar powered bird house, comprising:
a bird house structure;
an electrical subsystem comprising a lighting element configured for illuminating exterior features of the bird house; and
a solar energy system operably associated with the bird house structure, the solar energy system comprising:
a rechargeable electrical power source conductively coupled to the electrical subsystem; and
a solar energy recharging system for recharging the rechargeable electrical power source.

2. The solar powered bird house according to claim 1, wherein the electrical subsystem is a lighting system.

3. The solar powered bird house according to claim 2, wherein the lighting system includes at least one light emitting diode lighting element.

4. The solar powered bird house according to claim 2, wherein the lighting system includes a lighting element wherein the lighting element is selected from the group consisting of organic light emitting diode lighting element, cold cathode ray tube lighting element, incandescent bulb lighting element, and fluorescent lighting element.

5. The solar powered bird house according to claim 1, wherein the rechargeable electrical power source is at least one rechargeable battery.

6. The solar powered bird house according to claim 1, wherein the rechargeable electrical power source is selected from the group consisting of a rechargeable battery pack, a capacitor, and a fuel cell.

7. The solar powered bird house according to claim 1, wherein the rechargeable electrical power source is adapted to be recharged by a source of alternating current.

8. The solar powered bird house according to claim 1, wherein the bird house is defined by a decorative architectural structure.

9. The solar powered bird house according to claim 1, wherein the bird house is configured as a colony-type bird house.

10. The solar powered bird house according to claim 1, wherein the electrical subsystem is selected from the group consisting of a sound system, a video system, a cooling system, a heating system, and a remote control system.

11. The solar powered bird house according to claim 1, further comprising:
a support member for supporting the bird house structure.

12. The solar powered bird house according to claim 1, wherein at least a portion of the solar energy system is located remote from the bird house.

13. A solar module for a bird house, comprising:
a housing;
a solar energy system carried by the housing, comprising:
a rechargeable electrical power source; and
a solar energy recharging system for recharging the rechargeable electrical power source; and
an electrical subsystem conductively coupled to the rechargeable electrical power source, the electrical subsystem comprising a lighting element configured for illuminating exterior features of the bird house.

14. The solar module according to claim 13, wherein the electrical subsystem is a lighting system.

15. The solar module according to claim 14, wherein the lighting system includes at least one light emitting diode lighting element.

16. The solar module according to claim 14, wherein the lighting system includes a lighting element wherein the lighting element is selected from the group consisting of an organic light emitting diode lighting element, a cold cathode ray tube lighting element, an incandescent bulb lighting element, and a fluorescent lighting element.

17. The solar module according to claim 13, wherein the rechargeable electrical power source is at least one rechargeable battery.

18. The solar module according to claim 13, wherein the rechargeable electrical power source is selected from the group consisting of a rechargeable battery pack, a capacitor, and a fuel cell.

19. The solar module according to claim 13, wherein the rechargeable electrical power source is adapted to be recharged by a source of alternating current.

20. A solar powered bird house, comprising:
a base;
a support member coupled to the base;
a bird house structure slidingly carried on the support member;
an electrical subsystem comprising a lighting element configured for illuminating exterior features of the bird house; and
a solar energy system operably associated with the bird house structure, the solar energy system comprising:
a rechargeable electrical power source conductively coupled to the electrical subsystem; and
a solar energy recharging system for recharging the rechargeable electrical power source.

21. The solar powered bird house according to claim 20, wherein the rechargeable electric power source is carried in the base.

22. The solar powered bird house according to claim 20, wherein the solar energy system is carried at least partially within the base.

23. The solar powered bird house according to claim 20, further comprising:
an electrical raising and lowering system powered by the rechargeable electrical power source.
